(19) United States
(12) Patent Application Publication
(10) Pub. No.: US 2024/0192761 A1
(43) Pub. Date: Jun. 13, 2024

(54) High-Speed Multi-Standard Sampler Circuit

(71) Applicant: Apple Inc., Cupertino, CA (US)

(72) Inventors: Yudong Zhang, San Diego, CA (US); Ming-Shuan Chen, Santa Clara, CA (US); Chen-Yuan Wen, San Francisco, CA (US); Sanjeev K. Maheshwari, Fremont, CA (US)

(21) Appl. No.: 18/064,789

(22) Filed: Dec. 12, 2022

(51) Int. Cl. G06F 1/06; H03K 3/037

(52) U.S. Cl. CPC G06F 1/06; H03K 3/037; H03K 17/687

(57) ABSTRACT

A sampler circuit for use with a serial communication bus includes an amplifier circuit, an isolation circuit, and a latch circuit. During a first phase, the amplifier circuit amplifies a voltage difference between a first input signal and a second input signal received via the communication bus to generate a voltage difference on output nodes of the latch circuit. During an integration phase, the latch circuit increases the voltage difference on the output nodes. During a regeneration phase, the isolation circuit isolates the amplifier circuit from the latch circuit, which generates full-rail signals based on a voltage difference between the output nodes.

### BACKGROUND

### Technical Field

This disclosure relates to the field of high-speed communication interface design and, in particular, to high-speed sampler circuits.

### Description of the Related Art

Computing systems typically include a number of interconnected integrated circuits. In some cases, the integrated circuits may communicate using communication channels or links to transmit and receive data bits. The communication channels may support parallel communication, in which multiple data bits are transmitted in parallel, or serial communication, in which data bits are transmitted one bit at a time in a serial fashion.

The data transmitted between integrated circuits may be encoded to aid in transmission. For example, in the case of serial communication, data may be encoded to provide sufficient transitions between logic states to allow for clock and data recovery circuits to operate. Alternatively, in the case of parallel communication, the data may be encoded to reduce switching noise or to improve signal integrity.

During transmission of the data, the physical characteristics of the communication channel may attenuate a transmitted signal associated with a particular data bit. For example, the impedance of wiring included in the communication channel or link may attenuate certain frequency ranges of the transmitted signal. Additionally, impedance mismatches between wiring included in the communication channel and devices coupled to the communication channel may induce reflections of the transmitted signal, which may degrade subsequently transmitted signals corresponding to other data bits.

### BRIEF DESCRIPTION OF THE DRAWINGS

FIG. 1 is a block diagram of an embodiment of a sampler circuit for a receiver circuit in a computer system.

FIG. 2 is a block diagram of an embodiment of an amplifier circuit for a sampler circuit.

FIG. 3 is a block diagram of an embodiment of an isolation circuit for a sampler circuit.

FIG. 4 is a block diagram of an embodiment of a latch circuit for a sampler circuit.

FIG. 5 is a block diagram of an embodiment of a clock generator circuit for a sampler circuit.

FIG. 6 is a block diagram of an embodiment of a communication subsystem for a computer system.

FIG. 7 illustrates example waveforms associated with a sampler circuit.

FIG. 8 is a flow diagram of an embodiment of a method for operating a sampler circuit.

FIG. 9 is a block diagram of one embodiment of a system-on-a-chip that includes a sampler circuit.

FIG. 10 is a block diagram of various embodiments of computer systems that may include sampler circuits.

FIG. 11 illustrates an example of a non-transitory computer-readable storage medium that stores circuit design information.

While embodiments described in this disclosure may be susceptible to various modifications and alternative forms, specific embodiments thereof are shown by way of example in the drawings and will herein be described in detail. It should be understood, however, that the drawings and detailed description thereto are not intended to limit the embodiments to the particular form disclosed but, on the contrary, the intention is to cover all modifications, equivalents and alternatives falling within the spirit and scope of the appended claims.

### DETAILED DESCRIPTION OF EMBODIMENTS

Computing systems typically include a number of interconnected integrated circuits. In some cases, the integrated circuits may communicate using communication channels or links to transmit and receive signals that encode data symbols. The communication channels may support parallel communication, in which multiple data symbols are transmitted in parallel, or serial communication, in which data symbols are transmitted one bit at a time in a serial fashion. A given data symbol can correspond to a single bit of data or multiple bits of data.

The data transmitted between integrated circuits may be encoded to aid in transmission. For example, in the case of serial communication, data may be encoded to provide sufficient transitions between logic states to allow for clock and data recovery circuits to operate. Alternatively, in the case of parallel communication, the data may be encoded to reduce switching noise or to improve signal integrity.

When a transmitted signal is received, a sampler circuit can be employed to sample the received signals at particular points in time. In some cases, the sampling points are determined by a clock signal that is transmitted along with the data. In other cases, a clock is recovered from the received signal and the recovered clock signal is used to sample the signals.

Various types of sampler circuits may be employed. In some cases, a differential amplifier circuit may be used to compare respective voltage levels of received signals to one or more threshold values. Alternatively, a regenerative latch circuit can be employed to sample the received signals in order to generate logic values corresponding to data symbols encoded in the received signals.

When a regenerative latch circuit is used, the time from when a clock signal activates the regenerative latch circuit to when data appears on an output of the regenerative latch circuit (referred to as “clock-to-q”) is critical to system performance. As data rates have continued to increase, existing sampler circuits based on regenerative latches (e.g., strong ARM sampler, double-tail sampler, etc.) cannot satisfy specified clock-to-q timing which can result in functional failures at the higher data rates.

To meet specified performance targets, a new sampler circuit that employs a dedicated amplification phase is proposed. The new amplification phase decreases a duration of the integration phase of the latch circuit, while providing a larger voltage differential on the output nodes of the latch circuit before the latch enters its regeneration phase.

The embodiments described herein detail a new sampler circuit that employs a dedicated amplification stage that is used in conjunction with a regenerative latch circuit. The addition of the amplification stage reduces the duration of an integration phase of the latch circuit while providing a larger differential voltage on the output nodes of the latch circuit before the latch circuit enters its regenerative phase. The larger differential voltage allows for the regenerative phase to be activated sooner, reducing the clock-to-q timing, thereby improving performance.

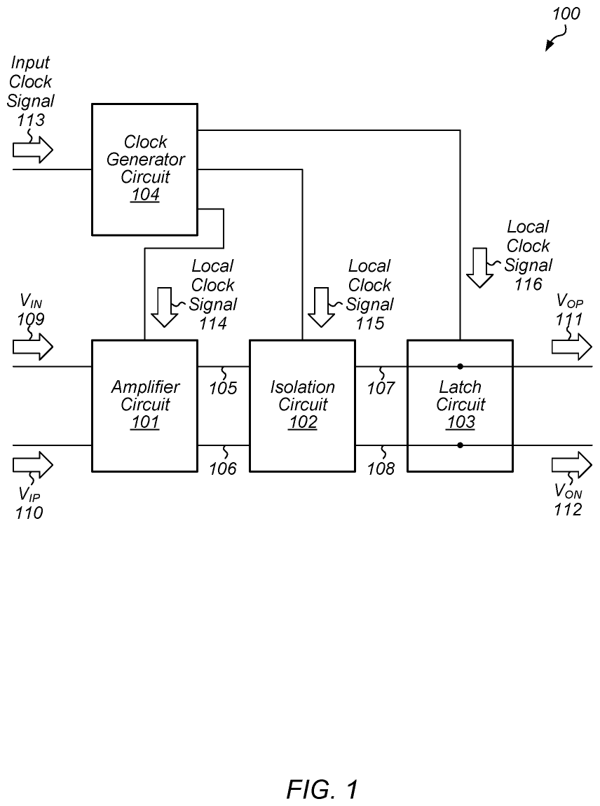

A block diagram depicting an embodiment of a sampler circuit is depicted in FIG. 1. As illustrated, sampler circuit 100 includes amplifier circuit 101, isolation circuit 102, latch circuit 103, and clock generator circuit 104.

Amplifier circuit 101 is configured to amplify, during a first time period, a difference between V_{IP} 110 and V_{IN} 109 to generate a voltage difference between nodes 107 and 108. As described below, V_{IP} 110 and V_{IN} 109 may be signals that differentially encode a value of a data symbol transmitted via a serial communication bus. In various embodiments, the data symbol may correspond to the values of one or more bits of data.

Latch circuit 103 is configured to increase, during a second time period subsequent to the first time period, the voltage difference between nodes 107 and 108. In various embodiments, to increase the voltage difference between nodes 107 and 108, latch circuit 103 may be further configured to decouple node 107 from node 108. It is noted that during the first and second time periods sampler circuit 100 can consume static current, i.e., the current drawn by sampler circuit 100 from a power supply remains relatively constant during the first and second time periods. Once the first and second time periods have elapsed, sampler circuit 100 only draws dynamic current associated with the switching of devices within isolation circuit 102 and latch circuit 103.

Latch circuit 103 is further configured to regenerate, during the third time period subsequent to the second time period, respective voltages of nodes 107 and 108 to generate a particular voltage level, e.g., V_{OP} 111 or V_{ON} 112, on at least one of the first output node or the second output node that corresponds to a value of a corresponding one of the plurality of data symbols. During a fourth time period subsequent to the third time period, latch circuit 103 may be further configured to pre-charge output nodes 107 and 108 during a recovery phase.

Isolation circuit 102 is configured to decouple amplifier circuit 101 from nodes 107 and 108 during the third time period. As described below, isolation circuit 102 may include multiple switch devices configured to decouple node 107 from node 105, and to decouple node 108 from node 106.

Clock generator circuit 104 is configured to receive input clock signal 113 and to generate local clock signals 114-116. In various embodiments, amplifier circuit 101 may be configured to amplify the difference between V_{IP} 110 and V_{IN} 109 using local clock signal 114. In a similar fashion, isolation circuit 12 is configured to decoupled amplifier circuit 101 from nodes 107 and 108 using local clock signal 115, and latch circuit 103 is configured to perform the regeneration operation described above using local clock signal 116.

As described below, to generate local clock signals 114-116, clock generator circuit 104 may employ a string of logic gates to introduce varying amounts of delay from input clock signal 113 and corresponding ones of local clock signals 114-116. The delay between any two of input clock signal 113 and local clock signals 114-116 may define a duration of one of the aforementioned time periods.

The absolute duration of any of the aforementioned time periods may vary from one sampler circuit to another and may be based on such things as a frequency of input clock signal 113. In some embodiments, the relative durations of the time periods may be consistent across different sampler circuit implementations. For example, in some cases, the duration of the first and second time periods may correspond to twice a gate delay of an inverter circuit, while the durations of the third and fourth time periods may correspond to a difference between half of the period of input clock signal 113 and twice the gate delay of an inverter circuit. It is noted that such durations are examples and that, in other embodiments, different durations may be employed.

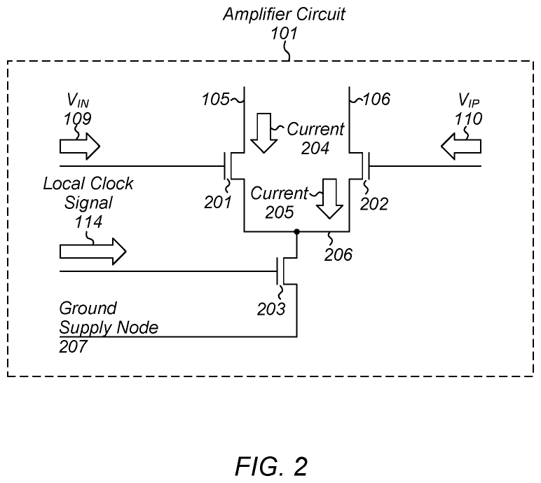

Turning to FIG. 2, a block diagram of an embodiment of amplifier circuit 101 is depicted. As illustrated, amplifier circuit 101 includes transistors 201-203. It is noted that although transistors 201-203 are depicted as being single transistors, in other embodiments, one or more of transistors 201-203 may be implemented using multiple transistors coupled together in parallel.

Transistor 201 is coupled between node 105 and node 206, and is controlled by V_{IN} 109. In a similar fashion, transistor 202 is coupled between node 106 and node 206, and is controlled by V_{IP} 110. Transistor 203 is coupled between node 206 and ground supply node 207, and is controlled by local clock signal 114.

In response to an activation of local clock signal 114, transistor 203 is configured to couple node 206 to ground supply node 207. By coupling node 206 to ground supply node 207, node 206 acts as a “virtual ground” and respective currents flowing through transistors 201 and 202 are determined, in part, by their respective gate-to-source voltages. For example, a value of current 204 is determined by a voltage level of V_{IN} 109, while a value of current 205 is determined by a voltage level of V_{IP} 110.

Current 204 discharges node 105 from its pre-charged level and current 205 discharges node 106 from its pre-charge level. After both node 105 and node 106 have been partially discharged by currents 204 and 205, respectively, a difference between respective voltage levels of nodes 105 and 106 may be proportional to a difference in respective voltage levels of V_{IN} 109 and V_{IP} 110. Depending on the respective transconductances of transistors 201 and 202, the difference in respective voltage levels of V_{IN} 109 and V_{IP} 110 can be amplified so that the voltage difference between nodes 105 and 106 is greater than the difference between the respective voltage levels of V_{IN} 109 and V_{IP} 110. Such amplification may, in various embodiments, allow the difference between the respective voltage levels of V_{IN} 109 and V_{IP} 110 to be maximized before the differential voltage is transferred to latch circuit 103.

As used herein, when a signal is activated, it is set to a logic or voltage level that activates a load circuit or device. The logic level may be either a high logic level or a low logic level depending on the load circuit. For example, an active state of a signal coupled to a p-channel MOSFET is a low logic level (referred to as an “active low signal”), while an active state of a signal coupled to an n-channel MOSFET is a high logic level (referred to as an “active high signal”).

In various embodiments, transistors 201-203 may be implemented as n-channel metal-oxide semiconductor field-effect transistors (MOSFETs), fin field-effect transistors (FinFETs), gate-all-around field-effect transistors (GAAFETs), or any other suitable transconductance devices.

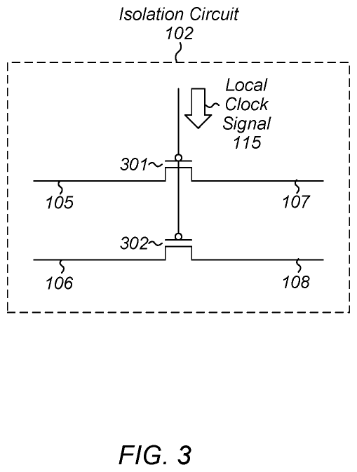

Turning to FIG. 3, a block diagram of an embodiment of isolation circuit 102 is depicted. As illustrated, isolation circuit 102 includes transistors 301 and 302. It is noted that although transistors 301 and 302 are depicted as being individual transistors, in other embodiments, either of transistors 301 or 302 may be implemented using multiple transistors coupled together in parallel.

Transistor 301 is coupled between node 105 and node 107, while transistor 302 is coupled between node 106 and node 108. Both transistors 301 and 302 are controlled by local clock signal 115.

Transistor 301 is configured to couple node 105 to node 107 in response to an activation of local clock signal 115. In a similar fashion, transistor 302 is configured to couple node 106 to node 108 in response to the activation of local clock signal 115. When both transistors 301 and 302 are activated, a voltage difference between nodes 105 and 106 is propagated onto nodes 107 and 108. In response to local clock signal 115 being de-activated, transistors 301 and 302 are configured to decouple node 107 from node 105, and node 108 from node 106.

In various embodiments, transistors 301 and 302 may be implemented as p-channel MOSFETs, FinFETs, GAAFETs, or any other suitable transconductance devices. In some embodiments, transistors 301 and 302 may be replaced with full CMOS pass gates that include both n-channel and p-channel devices.

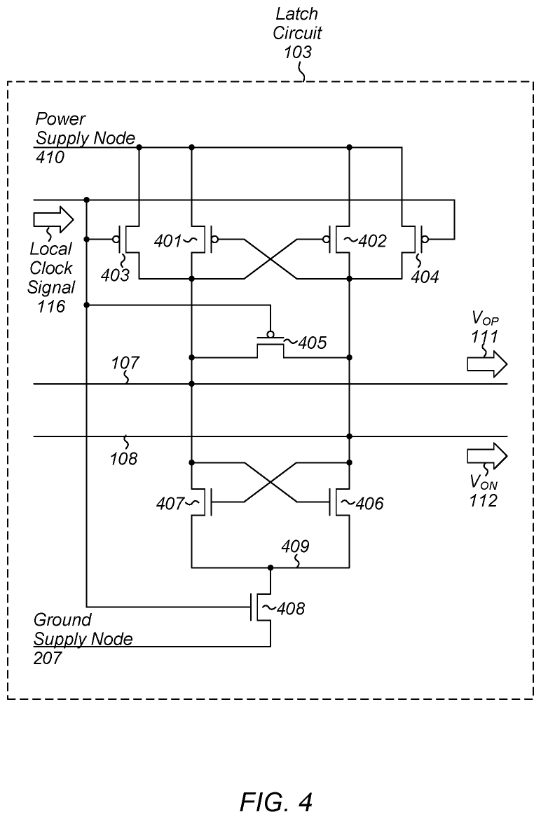

A block diagram of an embodiment of latch circuit 103 is depicted in FIG. 4. As illustrated, latch circuit 103 includes transistors 401-408. Although transistors 401-408 are depicted as being single transistors, in other embodiments, any of transistors 401-408 may be implemented using multiple transistors coupled together in parallel.

Transistor 401 is coupled between power supply node 410 and node 107, and is controlled by a voltage level of node 108. In a similar fashion, transistor 402 is coupled between power supply node 410 and node 108, and is controlled by a voltage level of node 108. It is noted that the particular arrangement of transistors 401 and 402 depicted in FIG. 4 is referred to as “cross coupling” and provides regenerative feedback between nodes 107 and 108.

Transistor 403 is coupled between power supply node 410 and node 107, and is controlled by local clock signal 116. In a similar fashion, transistor 404 is coupled between power supply node 410 and node 108, and is also controlled by local clock signal 116. In response to a determination that local clock signal 116 is at a low logic level, transistors 403 and 404 are configured to couple nodes 107 and 108, respectively, to power supply node 410. In various embodiments, coupling nodes 107 and 108 to power supply node 410 is referred to as “pre-charging” the nodes and sets V_{OP} 111 and V_{ON} 112 to a voltage level of power supply node 410 during a recovery time period.

Transistor 405 is coupled between node 107 and node 108, and is controlled by local clock signal 116. In response to a determination that local clock signal 116 is at a low logic level, transistor 405 is configured to couple node 107 to node 108 during the recovery time period. During the integration time period when local clock signal 116 is at a high logic level, transistor 405 is in an off state, decoupling node 107 from node 108, thereby allowing a differential voltage to develop between nodes 107 and 108 in response to respective currents sunk from nodes 107 and 108 by amplifier circuit 101.

Transistor 407 is coupled between node 107 and node 409, and is controlled by the voltage level of node 108. In a similar fashion, transistor 406 is coupled between node 108 and node 409, and is controlled by the voltage level of node 107. Like transistors 401 and 402, transistors 407 and 406 are arranged in a cross-coupled fashion and provide regenerative feedback between nodes 107 and 108.

Transistor 408 is coupled between node 409 and ground supply node 207, and is controlled by local clock signal 116. In response to a determination that local clock signal 116 is at a high logic level, transistor 408 is configured to couple node 409 to ground supply node 207, creating a virtual ground on node 409, allowing transistors 406 and 407 to further increase the differential on nodes 107 and 108 during the integration period.

In various embodiments, transistors 401-405 may be implemented as p-channel MOSFETs, FinFETs, GAAFETs, or any other suitable transconductance devices, while transistors 406-408 may be implemented as n-channel MOSFETs, FinFETs, GAAFETs, or any other suitable transconductance devices.

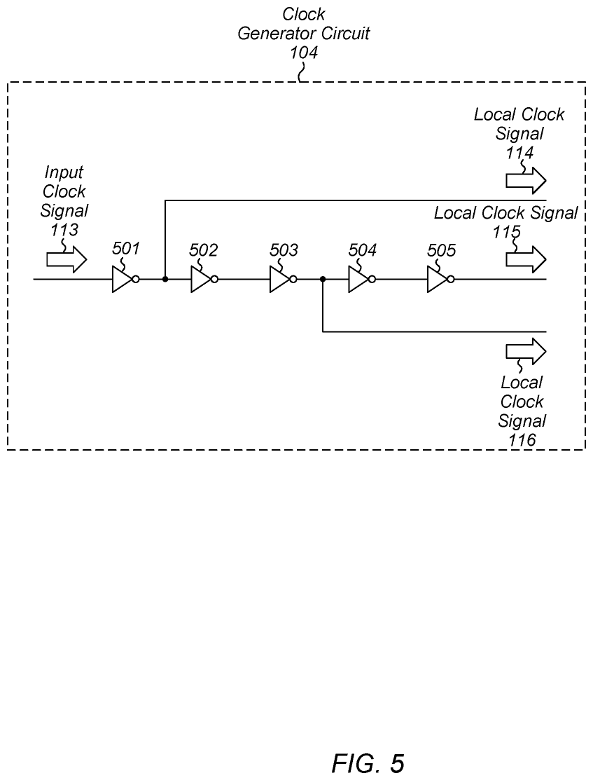

Turning to FIG. 5, a block diagram of an embodiment of clock generator circuit 104 is depicted. As illustrated, clock generator circuit 104 includes inverters 501-505.

Inverters 501-505 are coupled together in a serial fashion with the output of one inverter driving the input of the next. For example, the output of inverter 501 is coupled to the input of inverter 502. Each of inverters 501-505 are configured to generate respective output signals with an inverted logical sense of their corresponding input signals.

Additionally, each of inverters 501-505 are configured to generate transitions on their respective output signals after a delay period has elapsed since corresponding transitions on their respective input signals. The respective delays generated by inverters 501-505 result in particular phase relationships between local clock signals 114-116. For example, local clock signal 114 lags input clock signal 113 by a single inverter delay, while local clock signal 116 lags local clock signal 114 by two inverter delays, and local clock signal 115 lags local clock signal 116 by two inverter delays. The delays between the different clock signals are used to maintain desired durations of the different operation modes of sampler circuit 100. It is noted that in some embodiments, other circuit techniques, e.g., delay-locked loop circuits, may be employed to generate the desired phase relationships between the clock signals.

In various embodiments, inverters 501-505 may be implemented as complementary metal-oxide semiconductor (CMOS) logic gates. Alternatively, inverters 501-505 may be implemented using any suitable inverting amplifier circuit fabricated using a CMOS or any other suitable semiconductor manufacturing process.

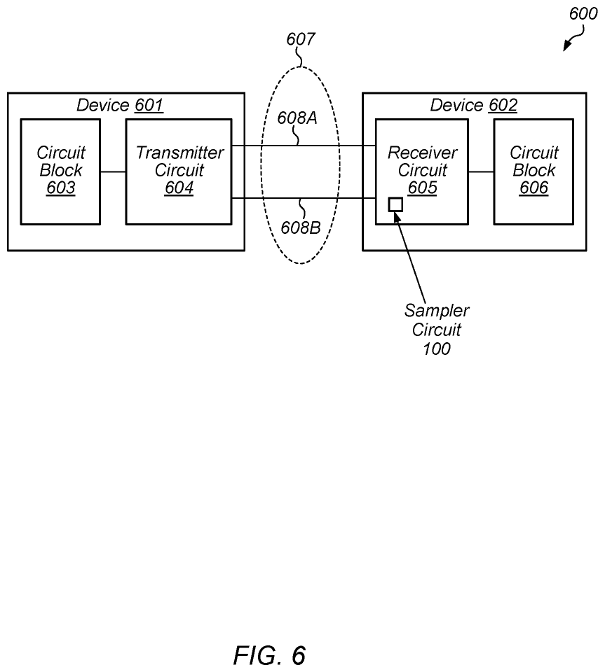

As described above, a receiver circuit that includes a sampler circuit, such as sampler circuit 100, may be employed in a computer system. A block diagram of an embodiment of such a computer system is depicted in FIG. 6. As illustrated, computer system 600 includes devices 601 and 602, coupled by communication bus 607.

Device 601 includes circuit block 603 and transmitter circuit 604. In various embodiments, device 601 may be a processor circuit, a processor core, a memory circuit, or any other suitable circuit block that may be included on an integrated circuit in a computer system. It is noted that although device 601 only depicts a single circuit block and a single transmitter circuit, in other embodiments, additional circuit blocks and additional transmitter circuits may be employed.

Transmitter circuit 604 is configured to serially transmit signals, via communication bus 607, corresponding to data received from circuit block 603. Such signals may differentially encode one or more bits such that a difference between the respective voltage levels of wires 608A and 608B, at a particular point in time, correspond to a particular bit value. In some cases, the generation of the signals may include encoding the bits prior to transmission. It is noted that although communication bus 607 is depicted as including two wires, in other embodiments, any suitable number of wires may be employed.

Device 602 includes receiver circuit 605 and circuit block 606. Like device 601, device 602 may be a processor circuit, a processor core, a memory circuit, or any other suitable circuit block configured to receive data from transmitter circuit 604. Receiver circuit 605 includes sampler circuit 100 that is configured to perform operations as described above.

Devices 601 and 602 may, in some embodiments, be fabricated on a common integrated circuit. In other embodiments, devices 601 and 602 may be located on different integrated circuits mounted on a common substrate or circuit board. In such cases, communication bus 607 may include metal or other conductive traces on the substrate or circuit board. Although only two devices are depicted in computer system 600, in other embodiments, any suitable number of devices may be employed.

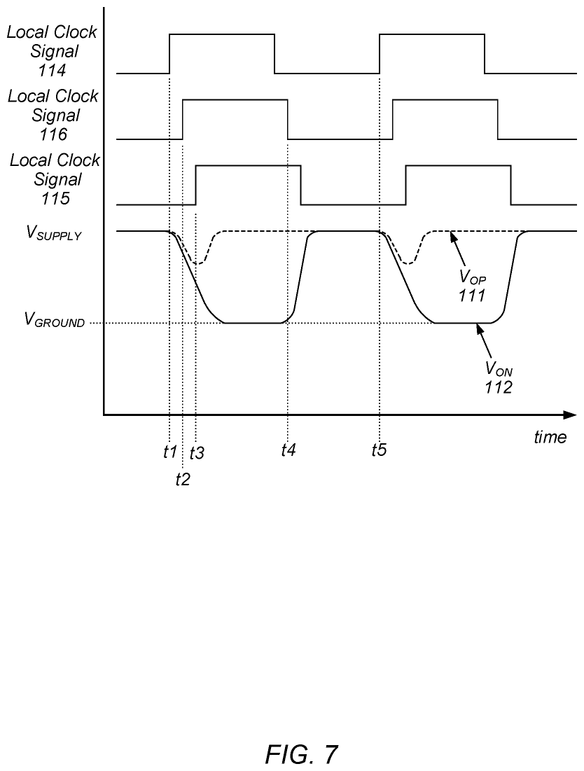

Turning to FIG. 7, example waveforms associated with the operation of a sampler circuit, such as sampler circuit 100 as depicted in FIG. 1, are illustrated. It is noted that the waveforms are just an example and that, in other embodiments, the waveforms may have different relative timings and different shapes.

At time t1, local clock signal 114 transitions from a low logic level to a high logic level, initiating an amplification period, where amplifier circuit 101 begins to discharge nodes 107 and 108 using V_{IP} 110 and V_{IN} 109 resulting in V_{OP} 111 and V_{ON} 112 decreasing in value from the pre-charge level of V_{SUPPLY}. As nodes 107 and 108 discharge, a differential develops between in V_{OP} 111 and V_{ON} 112 prior to the start of the integration period. By developing the differential before the integration period begins, the time needed to generate final values of V_{OP} 111 and V_{ON} 112 is reduced, improving the clock-to-q time for sampler circuit 100.

At time t2, local clock signal 116 transitions from a low logic level to a high level, ending the amplification period and starting the integration period. During the integration period, node 107 is decoupled from node 108, allowing a differential voltage to develop between V_{OP} 111 and V_{ON} 112. In this example, the values of V_{IP} 110 and V_{IN} 109 are such that V_{ON} 112 is discharged more than V_{OP} 111. The regenerative feedback of transistors 401 and 402 in latch circuit 103 begin to pull V_{OP} 111 towards V_{SUPPLY}, while V_{ON} 112 continues to decrease towards V_{GROUND}.

At time t3, local clock signal 115 transitions from a low logic level to a high logic level ending the integration phase and beginning the regeneration phase. During the regeneration phase, transistors 301 and 302 are de-activated, which decouples latch circuit 103 from amplifier circuit 101. The decoupling allows V_{ON} 112 to discharge to V_{GROUND} via transistor 406, while transistor 401 couples node 107 to power supply node 410, resulting in V_{OP} 111 charging to V_{SUPPLY}.

At time t4, local clock signal 116 transitions from a high logic level to a low logic level, initiating the recovery period. During the recovery period, transistor 405 is activated and node 107 is coupled to node 108. Additionally, transistors 403 and 404 are activated, charging nodes 107 and 108, resulting in V_{OP} 111 and V_{ON} 112 increasing to V_{SUPPLY}.

At time t5, local clock signal 114 again transitions from a low logic level to a high logic level, allowing sampler circuit 100 to sample V_{IP} 110 and V_{IN} 109 at a next point in time.

Various embodiments for sampling signal lines of a communication bus that encodes a stream of data symbols are disclosed. Broadly speaking, a sample circuit includes an amplifier circuit that may be configured to amplify, during a first time period, a difference between a first input signal and a second input signal to generate a voltage difference between a first output node and a second output node, where the first input signal and the second input signal encode a plurality of data symbols. A latch circuit may be configured to increase, during a second time period, the voltage difference between the first output node and the second output node, and an isolation circuit may be configured to decouple the amplifier circuit from the first output node and the second output node during a third time period. In various embodiments, the latch circuit may be further configured to regenerate, during the third time period, respective voltages of the first output node and the second output node to generate a particular voltage level on at least one of the first output node or the second output node that corresponds to a value of a corresponding one of the plurality of data symbols.

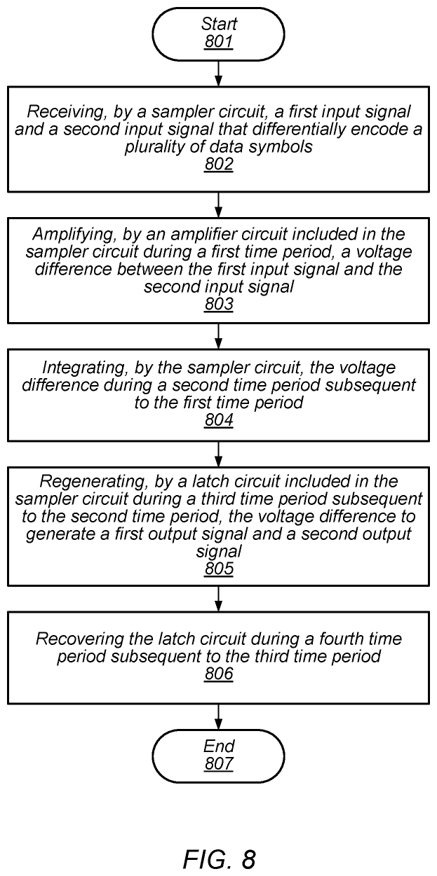

Turning to FIG. 8, a flow diagram depicting an embodiment of a method for operating a sampler circuit is illustrated. The method, which may be applied to various sampler circuits such as sampler circuit 100 as depicted in FIG. 1, begins in block 801.

The method includes receiving, by a sampler circuit, a first input signal and a second input signal that differentially encode a plurality of data symbols (block 802).

The method also includes amplifying, by an amplifier circuit included in the sampler circuit during a first time period, a voltage difference between the first input signal and the second input signal (block 803).

The method further includes integrating, by the sampler circuit, the voltage difference during a second time period subsequent to the first time period (block 804).

The method also includes regenerating, by a latch circuit included in the sampler circuit during a third time period subsequent to the second time period, the voltage difference to generate a first output signal and a second output signal (block 805). In some embodiments, the sampler circuit includes an isolation circuit, and regenerating the voltage difference includes isolating, by the isolation circuit, the amplifier circuit from the latch circuit.

In various embodiments, amplifying the voltage difference between the first input signal and the second input signal includes discharging a first output node of the latch circuit and a second output node of the latch circuit using the first input signal and the second input signal. In other embodiments, integrating the voltage difference includes decoupling the first output node of the latch circuit from the second output node of the latch circuit.

The method further includes recovering the latch circuit during a fourth time period subsequent to the third time period (block 806). In various embodiments, recovering the latch circuit includes pre-charging one or more circuit nodes included in the latch circuit to respective voltage levels. In some cases, the latch circuit includes a first output node and a second output node, and pre-charging the latch circuit includes coupling the first output node to the second output node, and charging the first output node and the second output node to a voltage level of a power supply node coupled to the latch circuit.

In some embodiments, the method may also include receiving, by a clock generator circuit included in the sampler circuit, a clock signal, and generating, by the clock generator circuit, a plurality of local clock signals using the clock signal. In such cases, the method may further include amplifying, by an amplifier circuit using a first local clock signal of the plurality of local clock signals, a voltage difference between the first input signal and the second input signal, integrating, by the sampler circuit, the voltage difference using a second local clock signal of the plurality of local clock signals, and regenerating, by a latch circuit using a third local clock signal of the plurality of local clock signals, the voltage difference to generate a first output signal and a second output signal. The method concludes in block 807.

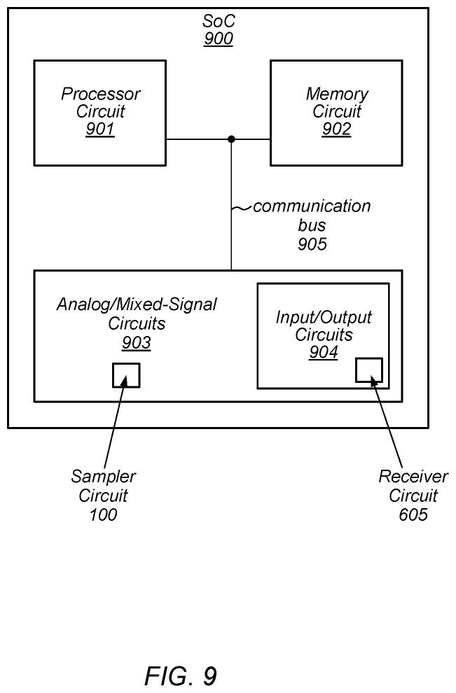

A block diagram of a system-on-a-chip (SoC) is illustrated in FIG. 9. In the illustrated embodiment, SoC 900 includes processor circuit 901, memory circuit 902, and analog/mixed-signal circuits 903, which includes input/output circuits 904. Processor circuit 901, memory circuit 902, and analog/mixed-signal circuits 903 are coupled to communication bus 905. In various embodiments, SoC 900 may be configured for use in a desktop computer, server, or in a mobile computing application such as, e.g., a tablet, laptop computer, or wearable computing device.

Processor circuit 901 may, in various embodiments, be representative of a general-purpose processor that performs computational operations. For example, processor circuit 901 may be a central processing unit (CPU) such as a microprocessor, a microcontroller, an application-specific integrated circuit (ASIC), or a field-programmable gate array (FPGA). In various embodiments, processor circuit 901 may include an instance of sampler circuit 100 that is used to sample communication bus in order to receive commands, data, and the like.

Memory circuit 902 may, in various embodiments, include any suitable type of memory such as a Dynamic Random-Access Memory (DRAM), a Static Random-Access Memory (SRAM), a Read-Only Memory (ROM), Electrically Erasable Programmable Read-only Memory (EEPROM), or a non-volatile memory, for example. It is noted that although a single memory circuit is illustrated in FIG. 9, in other embodiments, any suitable number of memory circuits may be employed. In some cases, memory circuit 902 may include an instance of sampler circuit 100 that is used to sample communication bus 905 in order to receive commands, data, and the like.

As illustrated, analog/mixed-signal circuits 903 includes sampler circuit 100. In various embodiments, analog/mixed-signal circuits 903 may also include a crystal oscillator circuit, a phase-locked loop (PLL) circuit, an analog-to-digital converter (ADC) circuit, and a digital-to-analog converter (DAC) circuit (all not shown). In other embodiments, analog/mixed-signal circuits 903 may be configured to perform power management tasks with the inclusion of on-chip power supplies and voltage regulator circuits

Input/output circuits 904, which may include receiver circuit 605, may be configured to coordinate data transfer between SoC 900 and one or more peripheral devices. Such peripheral devices may include, without limitation, storage devices (e.g., magnetic or optical media-based storage devices including hard drives, tape drives, CD drives, DVD drives, etc.), audio processing subsystems, or any other suitable type of peripheral devices. In some embodiments, input/output circuits 904 may be configured to implement a version of Universal Serial Bus (USB) protocol or IEEE 1394 (Firewire®) protocol.

Input/output circuits 904 may also be configured to coordinate data transfer between SoC 900 and one or more devices (e.g., other computing systems or integrated circuits) coupled to SoC 900 via a network. In one embodiment, input/output circuits 904 may be configured to perform the data processing necessary to implement an Ethernet (IEEE 802.3) networking standard such as Gigabit Ethernet or 10-Gigabit Ethernet, for example, although it is contemplated that any suitable networking standard may be implemented. In some embodiments, input/output circuits 904 may be configured to implement multiple discrete network interface ports.

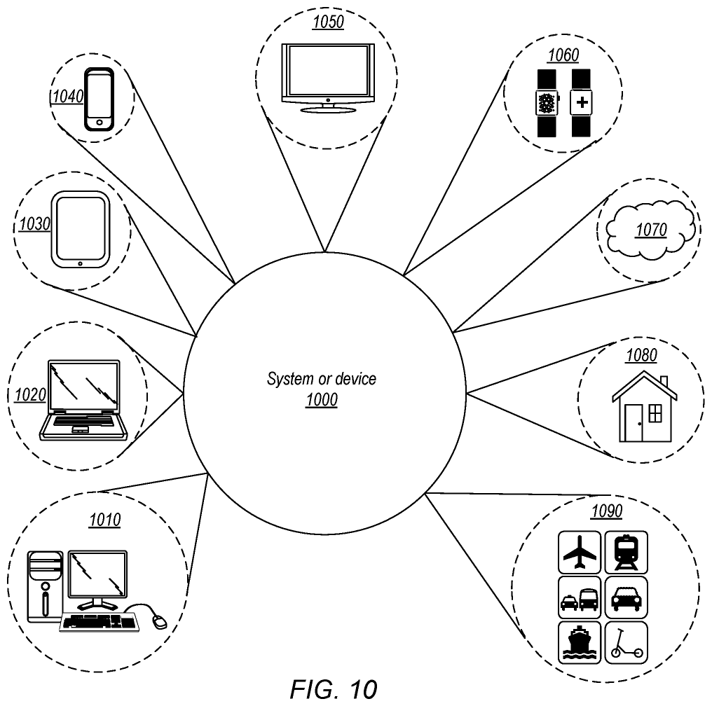

Turning now to FIG. 10, various types of systems that may include any of the circuits, devices, or systems discussed above are illustrated. System or device 1000, which may incorporate or otherwise utilize one or more of the techniques described herein, may be utilized in a wide range of areas. For example, system or device 1000 may be utilized as part of the hardware of systems such as a desktop computer 1010, laptop computer 1020, tablet computer 1030, cellular or mobile phone 1040, or television 1050 (or set-top box coupled to a television).

Similarly, disclosed elements may be utilized in a wearable device 1060, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1000 may also be used in various other contexts. For example, system or device 1000 may be utilized in the context of a server computer system, such as a dedicated server or on shared hardware that implements a cloud-based service 1070. Still further, system or device 1000 may be implemented in a wide range of specialized everyday devices, including devices 1080 commonly found in the home such as refrigerators, thermostats, security cameras, etc. The interconnection of such devices is often referred to as the “Internet of Things” (IoT). Elements may also be implemented in various modes of transportation. For example, system or device 1000 could be employed in the control systems, guidance systems, entertainment systems, etc. of various types of vehicles 1090.

The applications illustrated in FIG. 10 are merely exemplary and are not intended to limit the potential future applications of disclosed systems or devices. Other example applications include, without limitation: portable gaming devices, music players, data storage devices, unmanned aerial vehicles, etc.

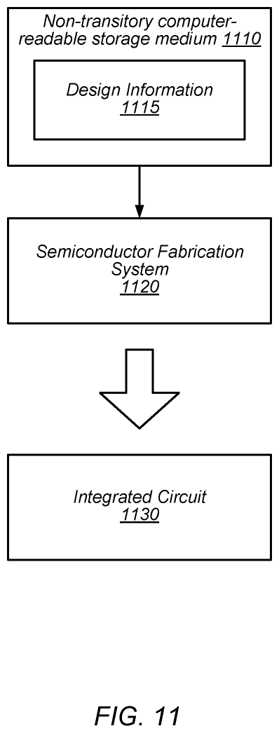

FIG. 11 is a block diagram illustrating an example of a non-transitory computer-readable storage medium that stores circuit design information, according to some embodiments. In the illustrated embodiment, semiconductor fabrication system 1120 is configured to process design information 1115 stored on non-transitory computer-readable storage medium 1110 and fabricate integrated circuit 1130 based on design information 1115.

Non-transitory computer-readable storage medium 1110 may comprise any of various appropriate types of memory devices or storage devices. Non-transitory computer-readable storage medium 1110 may be an installation medium, e.g., a CD-ROM, floppy disks, or tape device; a computer system memory or random-access memory such as DRAM, DDR RAM, SRAM, EDO RAM, Rambus RAM, etc.; a non-volatile memory such as Flash, magnetic media, e.g., a hard drive, or optical storage; registers, or other similar types of memory elements, etc. Non-transitory computer-readable storage medium 1110 may include other types of non-transitory memory as well or combinations thereof. Non-transitory computer-readable storage medium 1110 may include two or more memory mediums, which may reside in different locations, e.g., in different computer systems that are connected over a network.

Design information 1115 may be specified using any of various appropriate computer languages, including hardware description languages such as, without limitation: VHDL, Verilog, SystemC, System Verilog, RHDL, M, MyHDL, etc. Design information 1115 may be usable by semiconductor fabrication system 1120 to fabricate at least a portion of integrated circuit 1130. The format of design information 1115 may be recognized by at least one semiconductor fabrication system, such as semiconductor fabrication system 1120, for example. In some embodiments, design information 1115 may include a netlist that specifies elements of a cell library, as well as their connectivity. One or more cell libraries used during logic synthesis of circuits included in integrated circuit 1130 may also be included in design information 1115. Such cell libraries may include information indicative of device or transistor-level netlists, mask design data, characterization data, and the like, of cells included in the cell library.

Integrated circuit 1130 may, in various embodiments, include one or more custom macrocells, such as memories, analog or mixed-signal circuits, and the like. In such cases, design information 1115 may include information related to included macrocells. Such information may include, without limitation, schematics capture database, mask design data, behavioral models, and device or transistor-level netlists. As used herein, mask design data may be formatted according to graphic data system (GDSII), or any other suitable format.

Semiconductor fabrication system 1120 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1120 may also be configured to perform various testing of fabricated circuits for correct operation.

In various embodiments, integrated circuit 1130 is configured to operate according to a circuit design specified by design information 1115, which may include performing any of the functionality described herein. For example, integrated circuit 1130 may include any of various elements shown or described herein. Further, integrated circuit 1130 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components.

The present disclosure includes references to “embodiments,” which are non-limiting implementations of the disclosed concepts. References to “an embodiment,” “one embodiment,” “a particular embodiment,” “some embodiments,” “various embodiments,” and the like do not necessarily refer to the same embodiment. A large number of possible embodiments are contemplated, including specific embodiments described in detail, as well as modifications or alternatives that fall within the spirit or scope of the disclosure. Not all embodiments will necessarily manifest any or all of the potential advantages described herein.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

Particular features, structures, or characteristics may be combined in any suitable manner consistent with this disclosure. The disclosure is thus intended to include any feature or combination of features disclosed herein (either explicitly or implicitly), or any generalization thereof. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

For example, while the appended dependent claims are drafted such that each depends on a single other claim, additional dependencies are also contemplated. Where appropriate, it is also contemplated that claims drafted in one statutory type (e.g., apparatus) suggest corresponding claims of another statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to the singular forms such “a,” “an,” and “the” are intended to mean “one or more” unless the context dictates otherwise. Reference to “an item” in a claim thus does not preclude additional instances of the item.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” covering x but not y, y but not x, and both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of options. This phrase is not to be interpreted to require that there is at least one instance of w, at least one instance of x, at least one instance of y, and at least one instance of z.

Various “labels” may proceed nouns in this disclosure. Unless context provides otherwise, different labels used for a feature (e.g., “first circuit,” “second circuit,” “particular circuit,” “given circuit,” etc.) refer to different instances of the feature. The labels “first,” “second,” and “third,” when applied to a particular feature, do not imply any type of ordering (e.g., spatial, temporal, logical, etc.), unless stated otherwise.

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function. This unprogrammed FPGA may be “configurable to” perform that function, however.

Reciting in the appended claims that a structure is “configured to” perform one or more tasks is expressly intended not to invoke 35 U.S.C. § 112(f) for that claim element. Should Applicant wish to invoke Section 112(f) during prosecution, it will recite claim elements using the “means for” [performing a function] construct.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

What is claimed is:

1. An apparatus, comprising:
an amplifier circuit configured to amplify, during a first time period, a difference between a first input signal and a second input signal to generate a voltage difference between a first output node and a second output node, wherein the first input signal and the second input signal encode a plurality of data symbols;
a latch circuit configured to increase, during a second time period, the voltage difference between the first output node and the second output node; and
an isolation circuit configured to decouple the amplifier circuit from the first output node and the second output node during a third time period; and
wherein the latch circuit is further configured to regenerate, during the third time period, respective voltages of the first output node and the second output node to generate a particular voltage level on at least one of the first output node or the second output node that corresponds to a value of a corresponding one of the plurality of data symbols.

2. The apparatus of claim 1, wherein the latch circuit is further configured to pre-charge the first output node and the second output node during a fourth time period subsequent to the third time period.

3. The apparatus of claim 2, wherein the latch circuit is further configured to couple the first output node to the second output node during the fourth time period.

4. The apparatus of claim 1, wherein to amplify the voltage difference between the first input signal and the second input signal, the amplifier circuit is further configured to discharge the first output node and the second output node using the first input signal and the second input signal.

5. The apparatus of claim 1, wherein to increase the voltage difference, the latch circuit is further configured to decouple the first output node from the second output node during the second time period.

6. The apparatus of claim 1, further comprising a clock generator circuit configured to receive a clock signal, and generate a plurality of local clock signals using the clock signal; and
wherein the amplifier circuit is further configured to amplify, using a first local clock signal of the plurality of local clock signals, the voltage difference between the first input signal and the second input signal;
wherein the latch circuit is further configured to integrate the voltage difference using a second local clock signal of the plurality of local clock signals, and regenerate, using a third local clock signal of the plurality of local clock signals, the voltage difference to generate a first output signal and a second output signal;
wherein to increase the voltage difference, the latch circuit is further configured to increase the voltage difference between the first output node and the second output node using a second local clock signal of the plurality of local clock signals; and
wherein to regenerate the respective voltages of the first output node and the second output node, the latch circuit is further configured to regenerate the respective voltages of the first output node and the second output node using a third local clock signal of the plurality of local clock signals.

7. A method, comprising:
receiving, by a sampler circuit, a first input signal and a second input signal that differentially encode a plurality of data symbols;
amplifying, by an amplifier circuit included in the sampler circuit during a first time period, a voltage difference between the first input signal and the second input signal;
integrating, by the sampler circuit the voltage difference during a second time period subsequent to the first time period;
regenerating, by a latch circuit included in the sampler circuit during a third time period subsequent to the second time period, the voltage difference to generate a first output signal and a second output signal.

8. The method of claim 7, further comprising pre-charging the latch circuit during a fourth time period subsequent to the third time period.

9. The method of claim 8, wherein the latch circuit includes a first output node and a second output node, and wherein pre-charging the latch circuit includes:
coupling the first output node to the second output node; and
charging the first output node and the second output node to a voltage level of a power supply node coupled to the latch circuit.

10. The method of claim 8, wherein the sampler circuit includes an isolation circuit, and wherein regenerating the voltage difference includes isolating, by the isolation circuit, the amplifier circuit from the latch circuit.

11. The method of claim 8, wherein amplifying the voltage difference between the first input signal and the second input signal includes discharging a first output node of the latch circuit and a second output node of the latch circuit using the first input signal and the second input signal.

12. The method of claim 11, wherein integrating the voltage difference includes decoupling the first output node of the latch circuit from the second output node of the latch circuit.

13. The method of claim 7, further comprising:
receiving, by a clock generator circuit included in the sampler circuit, a clock signal;
generating, by the clock generator circuit, a plurality of local clock signals using the clock signal;
amplifying, by an amplifier circuit using a first local clock signal of the plurality of local clock signals, a voltage difference between the first input signal and the second input signal;
integrating, by the sampler circuit, the voltage difference using a second local clock signal of the plurality of local clock signals; and
regenerating, by a latch circuit using a third local clock signal of the plurality of local clock signals, the voltage difference to generate a first output signal and a second output signal.

14. An apparatus, comprising:
a first device configured to transmit, via a communication bus, a plurality of data symbols using a first input signal and a second input signal, wherein a value of a given data symbol of the plurality of data symbols is differentially encoded in respective voltage levels of the first input signal and the second input signal; and
a second device coupled to the communication bus that includes a sampler circuit configured to:
receive the first input signal and the second input signal;
amplify, during a first time period, a voltage difference between the first input signal and the second input signal;
integrate the voltage difference during a second time period subsequent to the first time period; and
regenerate, during a third time period subsequent to the second time period, the voltage difference to generate a first output signal and a second output signal.

15. The apparatus of claim 14, wherein the sampler circuit includes a latch circuit, and wherein the sampler circuit is configured to pre-charge the latch circuit during a fourth time period subsequent to the third time period.

16. The apparatus of claim 15, wherein the latch circuit includes a first output node and a second output node, and wherein to pre-charge the latch circuit, the sampler circuit is further configured to:
couple the first output node to the second output node; and
charge the first output node and the second output node to a voltage level of a power supply node coupled to the latch circuit.

17. The apparatus of claim 15, wherein to regenerate the voltage difference, the sampler circuit is further configured to isolate the latch circuit from an amplifier circuit included in the sampler circuit.

18. The apparatus of claim 15, wherein to amplify the voltage difference between the first input signal and the second input signal, the sampler circuit is further configured to discharge a first output node of the latch circuit and a second output node of the latch circuit using the first input signal and the second input signal.

19. The apparatus of claim 18, wherein to integrate the voltage difference, the sampler circuit is further configured to decouple the first output node of the latch circuit from the second output node of the latch circuit.

20. The apparatus of claim 13, wherein the sampler circuit includes a clock generator circuit configured to:
receive a clock signal; and
generate a plurality of local clock signals using the clock signal; and
wherein the sampler circuit is further configured to:
amplify, using a first local clock signal of the plurality of local clock signals, a voltage difference between the first input signal and the second input signal;
integrate the voltage difference using a second local clock signal of the plurality of local clock signals; and
regenerate, using a third local clock signal of the plurality of local clock signals, the voltage difference to generate a first output signal and a second output signal.
